(19) United States
(12) Patent Application Publication
(10) Pub. No.: US 2006/0028228 A1
(43) Pub. Date: Feb. 9, 2006

(54) Test pads for IC chip

(76) Inventor: Bor-Doou Rong, Hsinchu (TW)

Correspondence Address: HungChang Lin, 8 Schindler Ct., Silver Spring, MD, 20903, US

(21) Appl. No.: 10/911,425

(22) Filed: Aug. 5, 2004

(51) Int. Cl. G01R 31/26

(52) U.S. Cl. 324/765

(57) ABSTRACT

The testing pads for multi-chip package are alternately placed at two ends or open area of the chip, so that the spacing between the test pads is wide enough for test probes to access.

### BACKGROUND OF THE INVENTION

1. Field of the Invention

The invention relates to layout of bonding pads of an IC chip, particularly to the layout of the bonding pads for testing the chip

2. Brief Description of Related Art

In testing an IC chip, the test pads on the chip must be spaced far enough to allow the test probes to access. In recent development, there has been an approach to package more than one chip together. In such a case, the test pads require additional consideration. Recent development of the “board on chip” also requires the pads be arranged along a straight line in the middle of the chip.

FIG. 1 shows a prior art test pads layout. An IC chip 10 includes bonding pads “A” placed along the edges of the chip. To facilitate the interconnection with an adjacent chip (not shown), the bonding pads are rearranged and aligned along a straight line as pads “B” to shorten wire-bonding.

As an illustration, the chip 10 has eight metal bonding pads “A” along the sides of the chip 10. These group “A” bonding pads are wire connected by wires 11 to the second group of metal test pads “B”, which are aligned along the left side of the of the chip 10 to facilitate the wire bonding to another chip to the left (not shown).

Due to the close spacing of the test pads “B”, it is difficult to place test probes over them. To allow for test probe spacing, a third group of test pads “C” is added as shown in FIG. 2. The group “C” test probes are alternately butted to the left sides group “B” pads. Other group “C” pads are inserted in series to the wires 11 between the group “A” metal pads and the group “B” pads. Thus the spacing between the group “C” is widened to allow the placement of the test probes. However, such a layout does not distinguish whether there is a breakage of any bonding wire 11 between pad B and pad C.

### SUMMARY OF THE INVENTION

An object of the present invention is to arrange the test pads in for a chip for easy access of the test probes. Another object of the present invention is to save chip area for the test pads.

These objects are achieved by adding test pads alternately in two normal directions along two sides of the chip. Alternatively, the test pads can be arranged in some places where there is no circuit on the chip. The test pads are spaced far enough to allow easy access to test probes. These additional test pads are separately connected to the closely spaced in-line group “B” test pads without interrupting the connections between the group “A” pads and group “B” pads.

### BRIEF DESCRIPTION OF THE DRAWINGS

FIG. 1 shows a prior art chip without test pads suitable for probing.

FIG. 2 shows prior test pads for wider spacing suitable for probing.

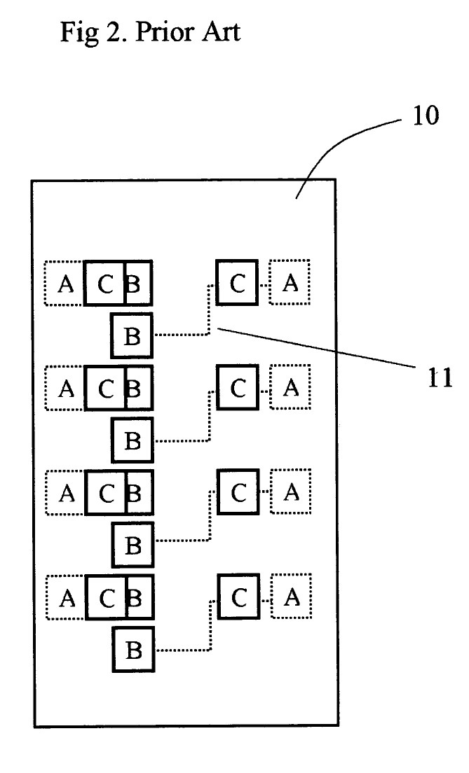

FIG. 3 shows the layout of the test pads of the present invention.

FIG. 4 shows a second embodiment of the present invention with test pads on open area.

### DETAILED DESCRIPTION OF THE INVENTION

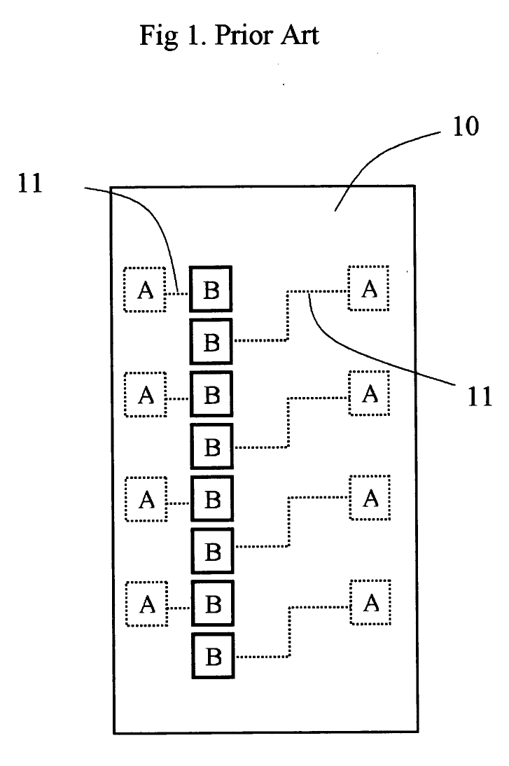

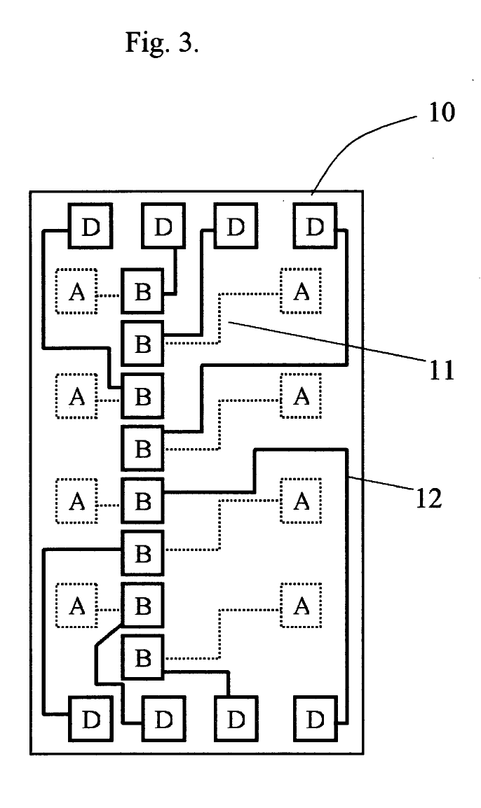

The basic layout of the present invention is shown in FIG. 3. In the prior art chip 10 shown in FIG. 1, additional test pads “D” are added along the two ends of the chip 10. The test pads are alternately connected to the closely-spaced group “B” pads. The spacing between the group “D” pads are wider than the spacing between the group “B” pads to allow the group “D” pads accessible to test probes. The connections between the group “B” pads and the group “D” pads are separate from and not in series with the connections between the group “A” pads and the group “B” pads.

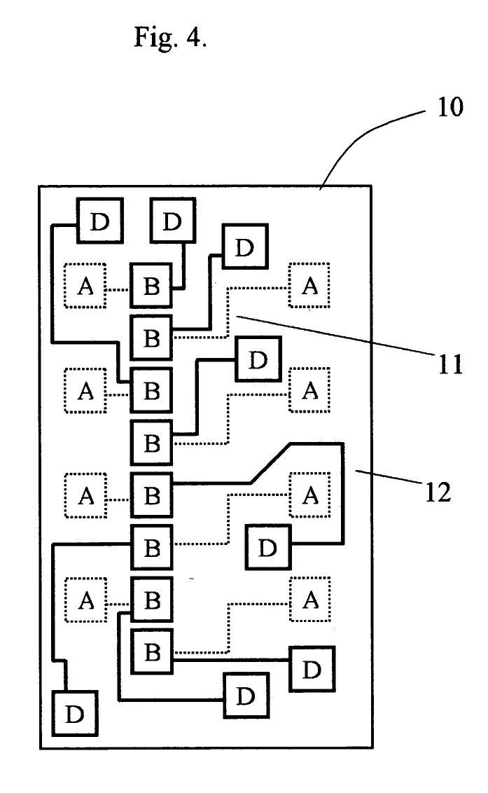

FIG. 4 shows a second embodiment of the present invention, where the test pads D are arranged in open area of the chip.

While the preferred embodiment of the invention has been described, it will be apparent to those skilled in the art that various modifications may be made without departing from the spirit of the invention. Such modifications are all within the scope of the present invention.

1. A probe testing system for testing an IC chip, comprising:
an integrated circuit (IC) chip;
a first group of pads serving as terminals of said IC chip;
a second group of pads aligned and connected to said first group of pads; and
a third group of test pads connected in parallel with said second group of pads without interrupting the connection between said first group of pads and said second group of pads, such that testing through said third group of pads can detect every abnormal connection from said second group of pads to said first group of pads and chips, and alternately laid out at open area of said chip, such that the spacing between adjacent third group of test pads is wider than that between the spacing between the second group of pads for convenient probing.

2. The probe testing system described in claim 1, wherein said second group of pads are aligned vertically in a column, and said third group of test pads are laid out horizontally.

3. The probe testing system as described in claim 1, wherein said second group of pads are at two horizontal ends of said chip.
